(19) United States
(12) Patent Application Publication
(10) Pub. No.: US 2012/0300400 A1
(43) Pub. Date: Nov. 29, 2012

(54) HEAT DISSIPATION ARRANGEMENT FOR POWER SUPPLY OF COMPUTER

(75) Inventor: Tsung-Yen Tsai, New Taipei City (TW)

(73) Assignee: SUPER FLOWER COMPUTER INC.

(21) Appl. No.: 13/478,120

(22) Filed: May 23, 2012

(30) Foreign Application Priority Data
May 25, 2011 (TW) 100209406

(51) Int. Cl. H05K 7/20

(52) U.S. Cl. 361/695

(57) ABSTRACT

The power supply includes a seat, a circuit module, a fan unit and a cover. The seat has a front panel and a rear panel with through holes. The circuit module is placed on a bottom of the seat. The fan unit is arranged in the seat, is electrically connected to the circuit module, and has a vent corresponding to the through holes in position. The cover fastened to the seat.

### BACKGROUND OF THE INVENTION

1. Technical Field

The invention relates to power supplies for personal computers, particularly to power supplies with a heat dissipation structure.

2. Related Art

A power supply is a device that supplies electric power to one or more electric loads. A regulated power supply is one that controls the output voltage or current to a specific value; the controlled value is held nearly constant despite variations in either load current or the voltage supplied by the power supply's energy source. Every power supply must obtain the energy it supplies to its load, as well as any energy it consumes while performing that task, from an energy source.

Usually, a power supply is provided with a fan for heat dissipation. The fan can generate air flow to carry heat out. However, there are many wires and components in a case of power supply, this will cause an impediment to air flow in the case and reduce the effect of heat dissipation.

To overcome the above drawback, a power supply with a large fan (12 cm or 14 cm) on the top panel appears in the market. However, such a large fan must have a large motor, so components under the motor cannot be blown by the fan. Another drawback is the air flow from the fan must right-angle sharply to the vents on side panels. This right-angled air flow is not good enough. Furthermore, according to the PS/2 specification, height of a PS/2 power supply is limited to 86 mm. A typical 12 cm or 14 cm fan usually has a height of 25 mm. A residually usable height of 50 mm remains only. Obviously, such a large fan will cause a serious restriction to other components. Some parts with larger sizes cannot be used due to this restriction.

### SUMMARY OF THE INVENTION

An object of the invention is to provide a power supply with a heat dissipation structure, which can reinforce the effect of heat dissipation without causing restriction to design and selection of other components.

To accomplish the above object, the power supply of the invention includes a seat, a circuit module, a fan unit and a cover. The seat has a front panel and a rear panel with through holes. The circuit module is placed on a bottom of the seat. The fan unit is arranged in the seat, is electrically connected to the circuit module, and has a vent corresponding to the through holes in position. The cover fastened to the seat.

### BRIEF DESCRIPTION OF THE DRAWINGS

FIG. 1 is an exploded view of the invention;

FIG. 2 is another exploded view of the invention;

FIG. 3 is an assembled view of the invention;

FIG. 4 is a schematic view of the invention in use;

FIG. 5 is a schematic view showing air flow;

FIG. 6 is a perspective view of another embodiment of the invention;

FIG. 7 is a perspective view of still another embodiment of the invention; and

FIG. 8 is a perspective view of yet another embodiment of the invention.

### DETAILED DESCRIPTION OF THE INVENTION

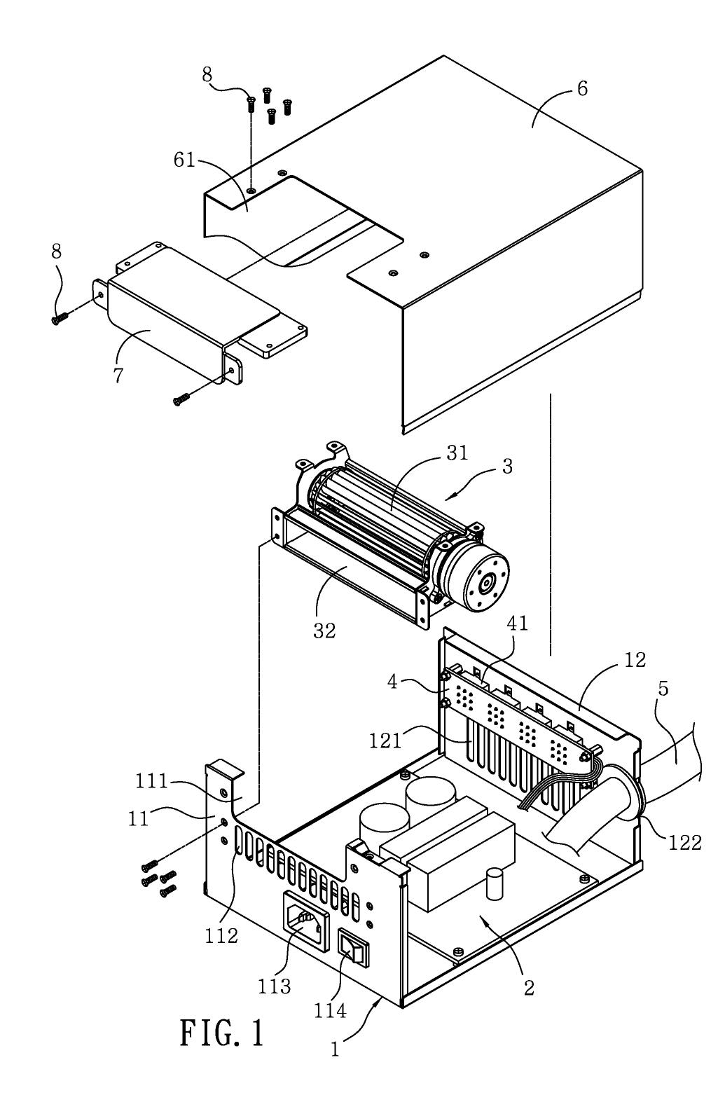

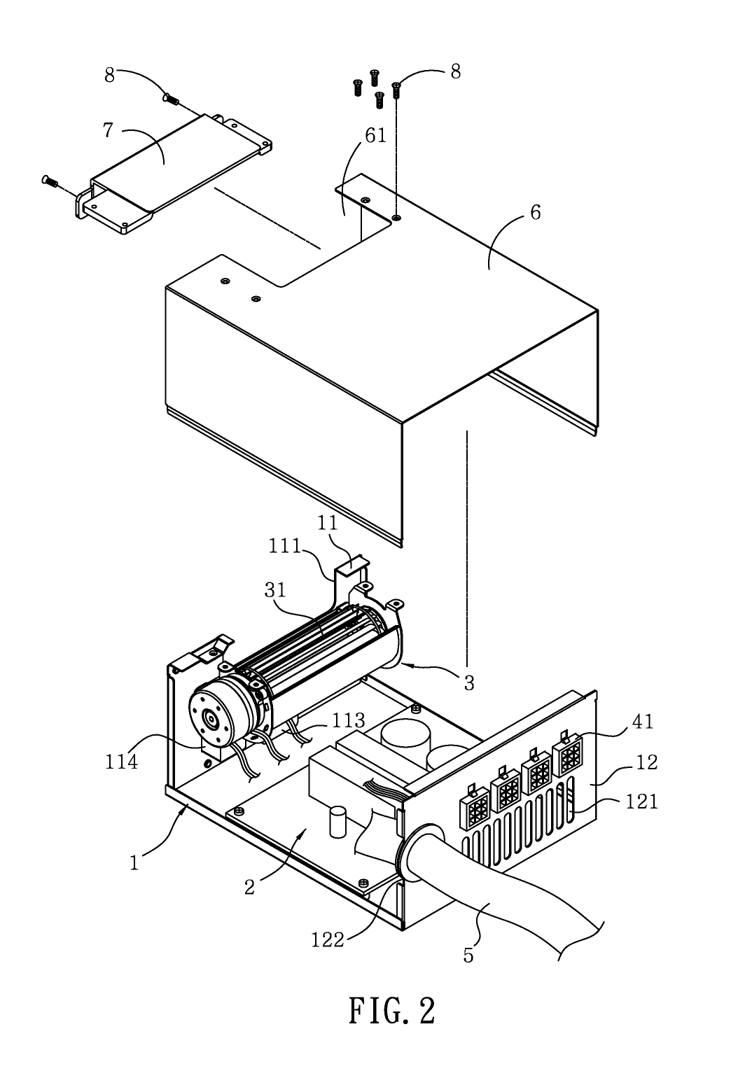

Please refer to FIGS. 1 and 2. The power supply of the invention includes a seat 1 having a front panel 11 and a rear panel 12. The rear panel 11 is formed with an indent 111 and a plurality of through holes 112 under the indent 111. A socket 113 is disposed under the through holes 112. A switch 114 is disposed beside the socket 113. A circuit module 2, which is electrically connected to the socket 113 and the switch 114, is placed on the bottom of the seat 1. A fan unit 3 is disposed in the seat 1 and electrically connected to the circuit module 2. In the shown embodiment, the fan unit 3 is a cross-flow fan. The fan unit 3 has a fan body 31 and a vent 32. The vent 32 is directly towards the through holes 112.

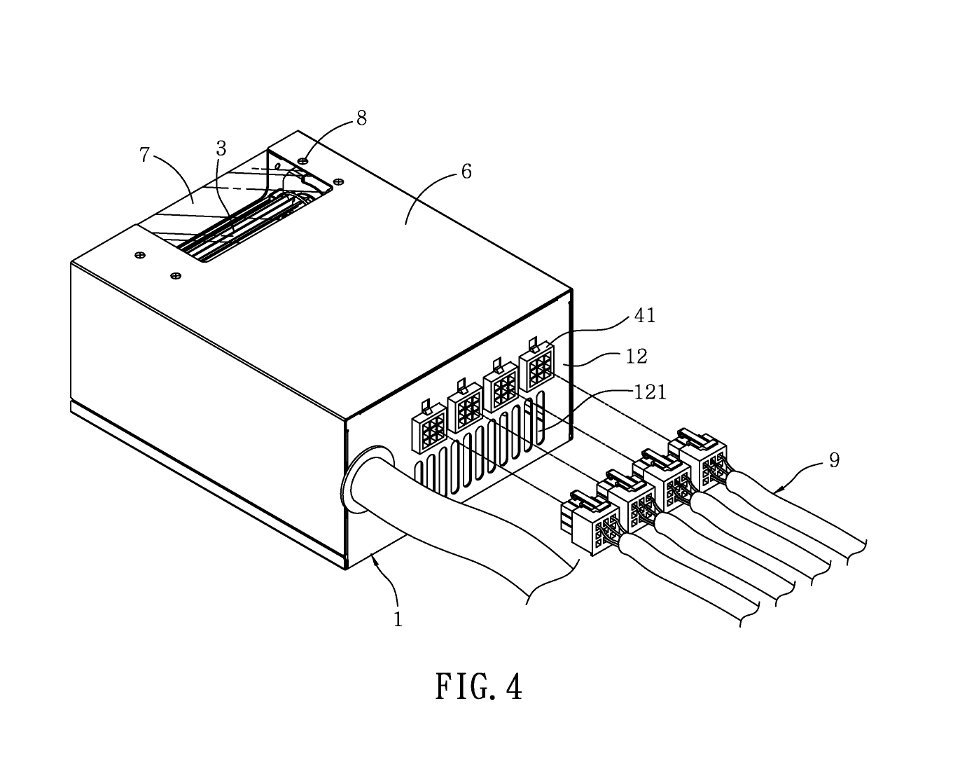

The front panel 12 is formed with a plurality of through troughs 121 and a connector set 4 is fastened on an inner side of the front panel 12. The connector set 4 is electrically connected to the circuit module 2 and has at least one connector 41. Four connectors 41 are shown in the figures. The connectors 41 penetrate and protrude from the front panel 12. As shown in FIG. 4, the connectors 41 are used for connecting cables 9. The front panel 12 is formed with a passing hole 122 for being passed through by a wire 5 electrically connected to the circuit module 2.

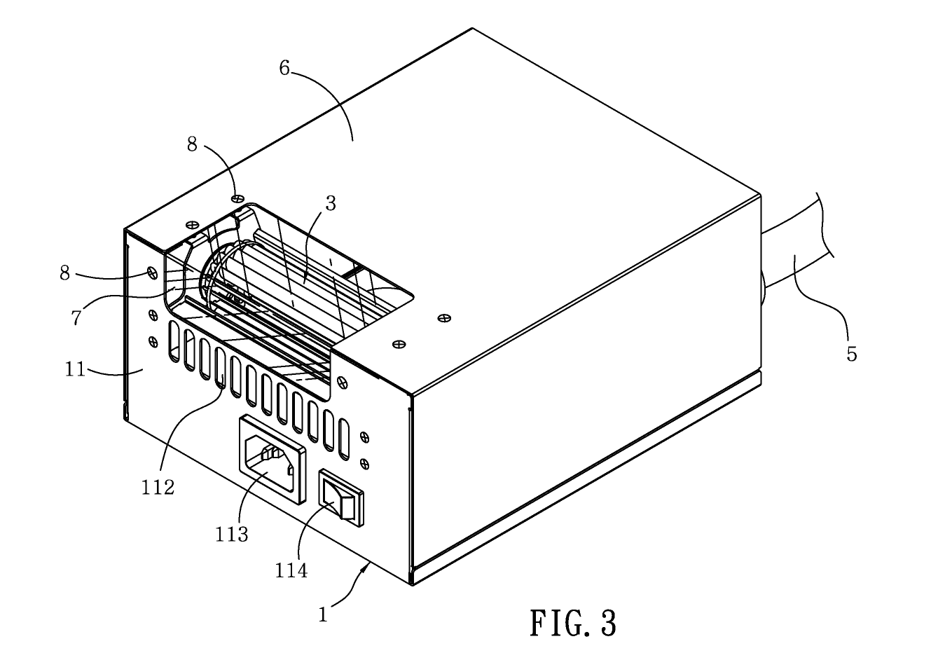

The seat 1 connects with a cover 6 with a U shape. The top of the cover 6 is formed with an opening 61. The opening 61 is located over the fan unit 3. The opening 61 is cloaked by a hood 7. Preferably, the hood 7 is transparent, which makes the fan unit 3 directly visible for checking its operation. The hood 7 is fastened onto the cover 6 by screws 8. The hood 7 is of an L shape and also cloaks the indent 111 as shown in FIG. 3.

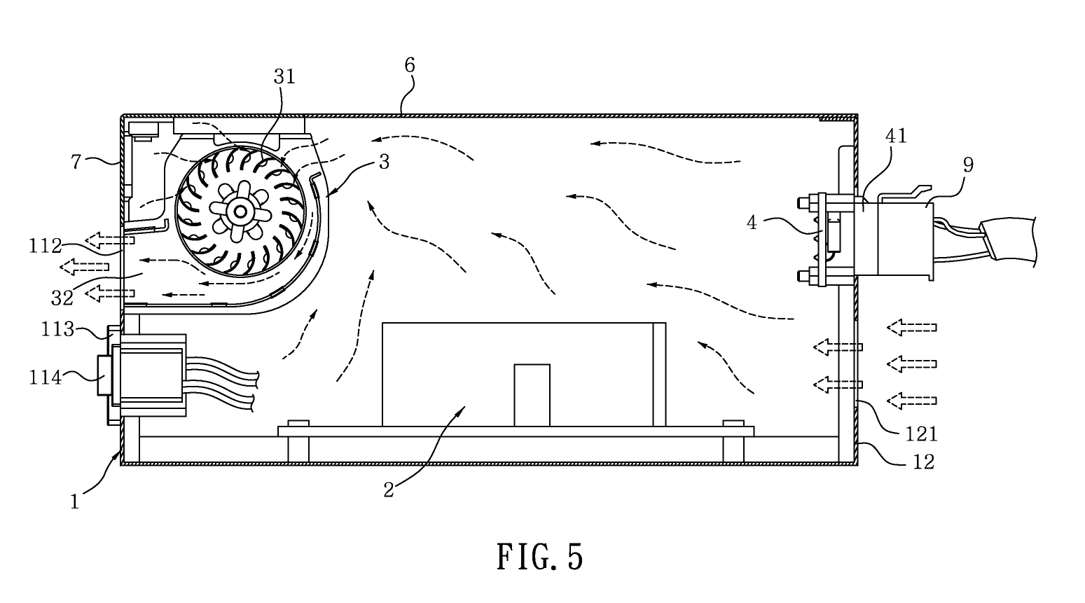

Please refer to FIGS. 4 and 5. The power supply is electrically connected to devices through the cables 9 for providing power. The heat from the circuit module 2 will make a heat exchange with cool air entering from the outside through the through troughs 121 as shown in FIG. 5. Air which has absorbed heat will rise up. Because the invention keeps a free space in the upper portion of the seat 1 to accommodate the heated air, the fan unit 3 can rapidly eject it to the outside through the vent 32 and the through holes 112. It should be noted that the inner space of the power supply is kept as free as possible. This will not cause a restriction to design and selection of components.

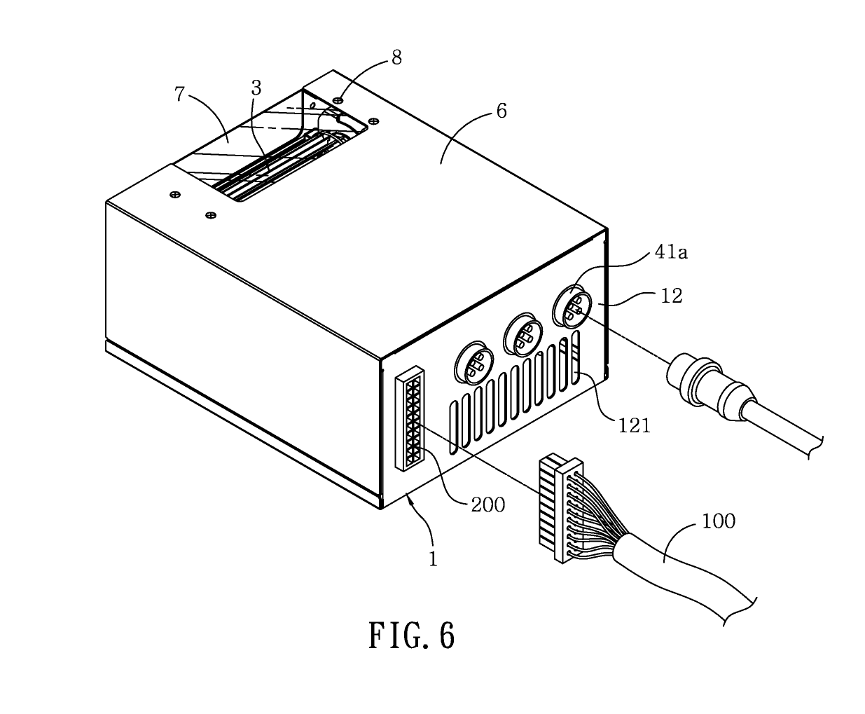

Please refer to FIG. 6, which shows another embodiment of the invention. In this embodiment, the wire 5 is replaced with a female connector 200 electrically connected to the circuit module 2. The female connector 200 can be connected by a wire with a male connector 100. Also, the connector 41a is of a round shape in this embodiment.

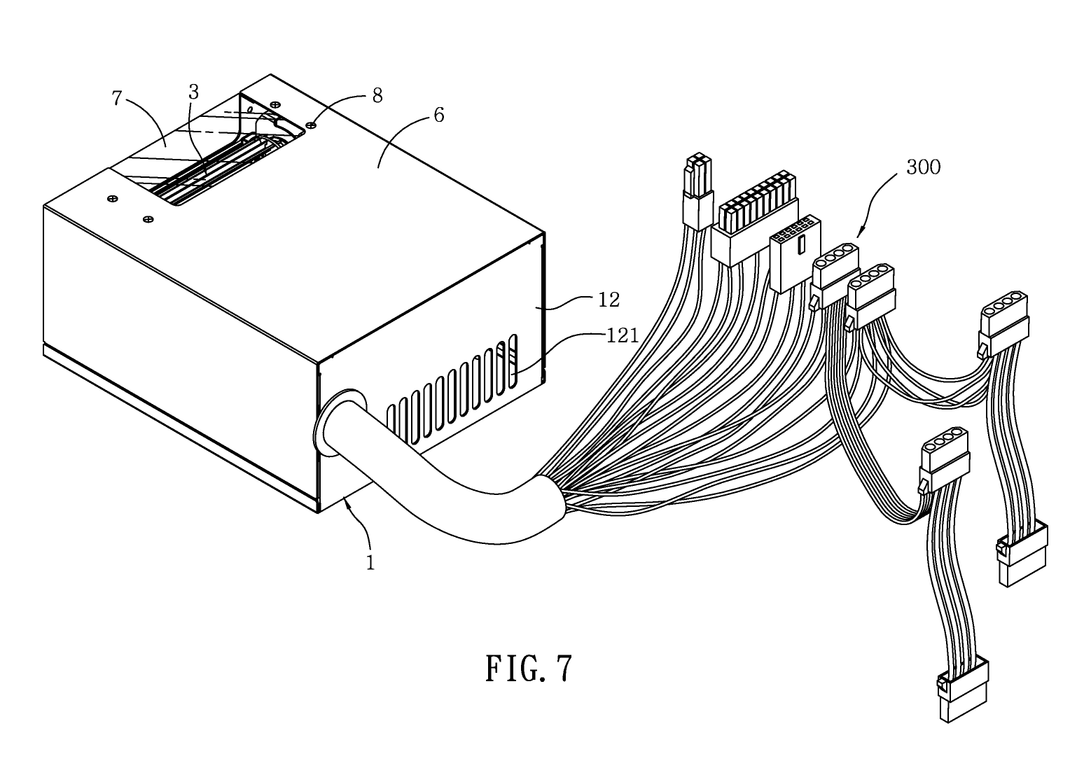

FIG. 7 shows still another embodiment of the invention. As shown in the figure, the connector set 4 and wire 5 are combined together to form a set of connectors 300 with different types.

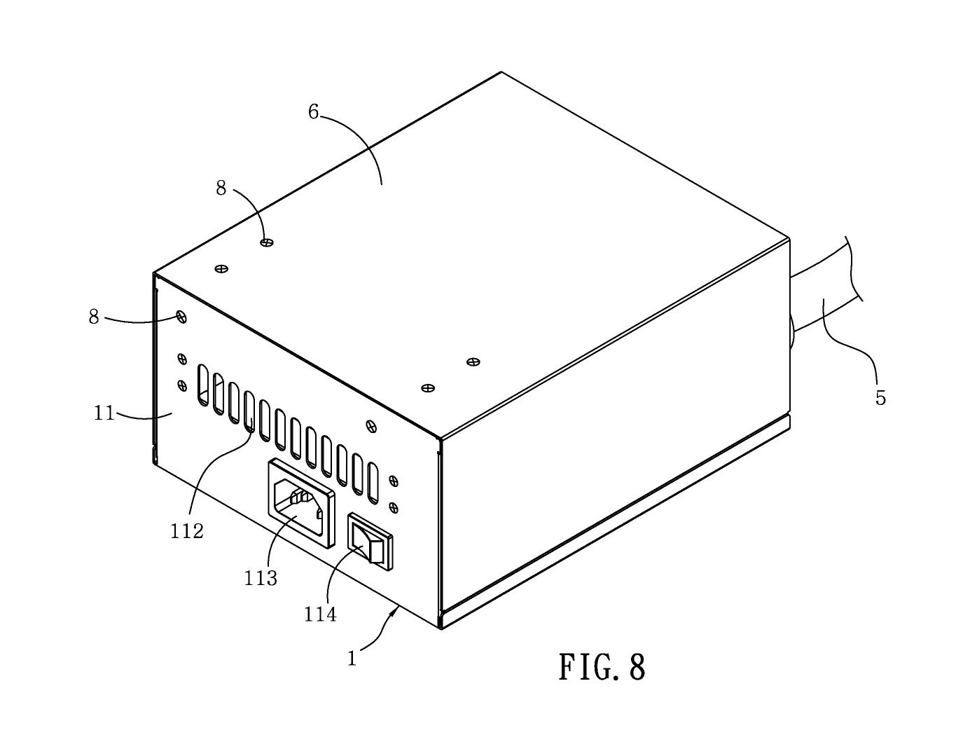

It should be noted that the hood 7 is not essential and can be omitted as shown in FIG. 8. In this embodiment, the cover 6 is formed without the opening 61.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A power supply comprising:
a seat, having a front panel and a rear panel with through holes;
a circuit module on a bottom of the seat;
a fan unit, arranged in the seat, electrically connected to the circuit module, and having a vent corresponding to the through holes in position; and
a cover fastened to the seat.

2. The power supply of claim 1, wherein the rear panel is provided with a socket.

3. The power supply of claim 1, wherein the rear panel is provided with a switch.

4. The power supply of claim 1, wherein the front panel is formed with a connector set having at least one connector and electrically connected to the circuit module.

5. The power supply of claim 1, wherein the front panel is formed with a passing hole.

6. The power supply of claim 5, further comprising a wire passing through the passing hole to electrically connect with the circuit module.

7. The power supply of claim 6, wherein the wire connects a set of connectors.

8. The power supply of claim 5, wherein the passing hole is disposed with a female connector electrically connected to the circuit module.

9. The power supply of claim 1, wherein the cover is of a U shape.

10. The power supply of claim 1, wherein the rear panel is formed with an indent, a top of the cover is formed with an opening corresponding to the fan unit in position, and the opening and the indent are cloaked by a hood.

11. The power supply of claim 10, wherein the hood is of an L shape.

12. The power supply of claim 11, wherein the hood is transparent.

13. The power supply of claim 1, wherein the fan unit is a cross-flow fan.

14. The power supply of claim 1, wherein the front panel is formed with a plurality of through troughs.

15. The power supply of claim 1, wherein the rear panel is formed with a plurality of through holes.
